(19) United States
(12) Patent Application Publication
(10) Pub. No.: US 2004/0189504 A1
(43) Pub. Date: Sep. 30, 2004

(54) Semi-flash A/D converter with minimal comparator count

(75) Inventor: Uday Dasgupta, Singapore (SG)

Correspondence Address: GEORGE O. SAILE, 28 DAVIS AVENUE, POUGHKEEPSIE, NY, 12603, US

(73) Assignee: Agency For Science, Technology and Research

(21) Appl. No.: 10/403,445

(22) Filed: Mar. 31, 2003

(51) Int. Cl. H03M 1/12

(52) U.S. Cl. 341/156

(57) ABSTRACT

This circuit and method provides an analog-to-digital A/D converter with minimal power and minimal integrated circuit area. A circuit and a method for A/D conversion are provided which maintains performance, but which uses fewer comparators than the prior art. This is achieved by a semi-flash analog-to-digital, A/D, converter circuit with minimal comparator count. The design does not use any subtraction or multiplication operation. It utilizes fewer comparators than the prior art semi-flash A/D converters. The prior art designs use 30 comparators for an 8-bit semi-flash A/D converter while this invention uses 8 comparators. This circuit and method does not require any external Sample and Hold, S/H circuits. It is a hybrid between flash A/Ds and successive approximation A/Ds.

### BACKGROUND OF THE INVENTION

1. Field of the Invention

The present invention generally relates to the general problem of designing an analog-to-digital A/D converter with minimal power and minimal integrated circuit area. More particularly, this invention relates to a circuit and a method for A/D conversion which maintains performance, but which uses fewer comparators than the prior art.

2. Description of the Prior Art

The number of comparators used in flash A/D converters is (2 to the power I)−1 where I is the number of digital output bits. For I=8, the number of comparators is 255 which is prohibitively high. Two step semi-flash A/D converters can reduce the comparator count to ‘m’+‘n’ where n=2^{p}−1 and m=2^{q}−1, where p is the number of most significant bits MSB and q is the number of least significant bits, LSB (I=p+q). If p=q=4, then the comparator count for such an A/D converter is 15+15=30. However, since comparators take up large amounts of power and space, a further reduction in the number of comparators would be beneficial.

FIG. 1 shows a block diagram of a prior art 8-bit analog-to-digital A/D converter 110. The AND converter block 110 has an analog input, Vin 120. It has eight bits of digital output, VOUT₀₋₇. These eight outputs have either a logical ‘1’ level or a logical ‘0’ level. This type of A/D converter is known as a flash converter, since the digital output is obtained in one-step. A/D converter 110 shown in FIG. 1 has 255 comparators in its circuit implementation. This is a large amount of comparator circuitry, which occupies a large amount of silicon area. Flash or one-step A/D converters are known to require a large amount of comparator circuitry, consuming large power and silicon area.

FIG. 2 shows a prior art 8 bit D/A converter implemented with a 2-step circuit in order to reduce the amount of comparator circuitry. It contains two 4-bit flash (one-step) A/D converters, each of which contain 15 comparators as shown (210, 220). The analog input Vin 260 goes into the most significant bit MSB 4-bit A/D converter 210. The 4 digital bits of output 270 are the 4 most significant bits of the overall 8-bit A/D conversion primary output. In addition, these 4 MSB bits are fed into a 4-bit digital-to-analog D/A converter 230. The analog output, V1 of this block 230 is fed into a subtractor 240. The other leg of the subtractor 240 is the original analog signal 260. The remaining 4-bits (least significant bits-LSB) are found by determining the quantization error of the 4 MSB bits. To alleviate the circuit requirements, the quantization error output VQ of the subtractor 240 is multiplied by 16 by a gain amplifier 250. The analog output of the gain amplifier 250 is fed into the second 4-bit flash A/D block 220. The output of this block 220 produces the lower 4 bits (LSB) of the overall semi-flash (two-step) A/D converter of FIG. 2. The 2-step A/D converter of FIG. 2 only uses 30 comparators.

FIG. 3 shows a prior art 8-bit 2-step A/D converter with digital error correction. The analog input, Vin 310 goes into a first sample and hold S/H₁ circuit 330. This circuit 330 samples a voltage level of the analog input and holds its voltage level for a period of time. The output of this first S/H₁ block 330 goes into the analog input of the MSB A/D block 340 and also to the input of a second sample and hold S/H₂ circuit 350. The purpose of S/H₂ 350 is to allow the first S/H₁ block 330 to sample a new input signal before the gain amplifier 380 has finished settling. The performance of S/H₁ 330 is very critical, since its performance limits the overall linearity of the 8-bit A/D converter.

The purpose of the error correction of FIG. 3 is to significantly ease the design requirements of the MSB D/A block 340. Without error correction, the MSB A/D converter 340 needs to be at least 8 bit accurate. With error correction, the MSB block 340 only needs to be 4 bit accurate. The accuracy of the other circuit blocks in FIG. 3 is shown.

The blocks associated with the error correction process in FIG. 3 are a digital delay block 385, the error correction block 320, the 5-bit LSB A/D block 395, and the third sample and Hold S/H3 block 390. The blocks associated with the 2-stage semi-flash A/D corrector and the 4-bit MSB block 340, the 4-bit D/A 360, the subtractor 370, the gain amp 380, and the 5-bit LSB A/D 395.

U.S. Pat. No. 5,818,379 (Kim) “Flash Analog to Digital (A/D) Converter with Reduced Number of Comparators” describes an N-bit flash A/D converter with a reduced number of comparators. The A/D converter uses a reference voltage generator, an address generator, and a comparing portion.

U.S. Pat. No. 5,684,486 (Ono, et al.) “Flash A/D Converter” describes an A/D converter which includes a plurality of reference voltages and an input analog signal to absorb a current with a constant value from a non-inverted output or inverted output of each master comparator, a set of constant current sources, a set of load resistors, and a set of slave comparators for outputting desired digital signals.

U.S. Pat. No. 6,002,356 (Cooper) “Power Saving Flash A/D Converter” describes a flash A/D converter which includes an n-bit converter using a resistive-divider string which has tap points between each pair of adjacent resistors. All of the comparators of this design except the ones in the group containing the transition point are deactivated to conserve power during the A/D conversion process for a given sample.

### SUMMARY OF THE INVENTION

It is therefore an object of the present invention to provide a circuit and a method for providing an analog-to-digital A/D converter with minimal power and minimal integrated circuit area. It is further an object of this invention to provide a circuit and a method for A/D conversion which maintains performance, but which uses fewer comparators than the prior art.

The objects of this invention are achieved by a semi-flash analog-to-digital, A/D, converter circuit with minimal comparator count. It is made up of a digital-to-analog converter, DAC, which communicates to a switch array and with a control logic section, an ‘n’×‘m’ switch array, whose outputs drive comparators, a control logic section, a set of comparators, which interface between the DAC/switch array and between the control logic, and a set of buffers, which interface the control logic and the DAC and switch array. This semi-flash A/D converter circuit is also made up of a data output bus coming out of the control logic section and an analog input line going into one of two inputs of the comparators. This semi-flash A/D converter also contains a digital-to-analog D/A converter which contains a resistor divider connected between V_{R1} and V_{R2}, the terminal voltages of the reference voltage V_{REF}. The D/A converter DAC also has ‘n’ digital inputs, which come from the control logic. The DAC has ‘m−1’ analog outputs, which feed one input of the ‘m−1’ comparators. The switch array consists of ‘n’ switch resistor groups each containing ‘m’ switches, which interface different points along the resistor divider and with the ‘m−1’ analog output lines. The control logic section consists of a clock input, 8 digital data outputs, ‘m−1’ digital inputs from ‘m−1’ comparators, a sampling output, and ‘n’ switch data digital outputs, which feed into the DAC/switch array. The comparators compare the ‘m’ analog outputs from the DAC/switch array with the single analog primary input signal ranging from V_{R1} to V_{R2} which is to be converted by the invention to digital signals. The comparator uses the sampling output from the control logic to produce ‘m−1’ digital outputs which indicate which of the ‘m−1’ DAC analog outputs equal the voltage level of the primary analog input which comes into the A/D circuit. The buffers whose inputs come from ‘n’ digital outputs from the control logic, provide adequate drive to control the ‘n’ individual switch groups in the DAC/switch array. The clock signal into the control logic defines when to sample input. The clock signal into the control logic defines when to determine a plurality of most significant bits. This clock signal into the control logic defines when to determine a plurality of least significant bits. The clock signal into the control logic defines when to latch the most significant bits. The clock signal into the control logic defines when to output a plurality of data bits for previous sample. The clock signal into the control logic defines when to output a plurality of data bits for current sample. The switch data output from the control logic tells the DAC/switch array logic when to switch data from ‘n’ resistor group to the ‘m−1’ DAC/switch array analog output lines.

The above and other objects, features and advantages of the present invention will be better understood from the following detailed description taken in conjunction with the accompanying drawings.

### BRIEF DESCRIPTION OF THE DRAWINGS

FIG. 1 shows a prior art block high level diagram of a flash 8-bit analog-to-digital, A/D converter.

FIG. 2 shows a prior art block diagram of a two-stage semi-flash A/D converter.

FIG. 3 shows a prior art block diagram of a two-stage semi-flash A/D converter using error correction logic to ease the accuracy of the other semi-flash components.

FIG. 4 shows a block diagram of the main embodiment of this invention.

FIG. 5 shows a detailed circuit diagram of the digital-to-analog converter, DAC and switch array parts of the main embodiment of this invention.

FIG. 6 shows a block diagram of the comparator part of the main embodiment of this invention.

FIG. 7 shows a timing diagram which describes the control sequence of the main embodiment of this invention.

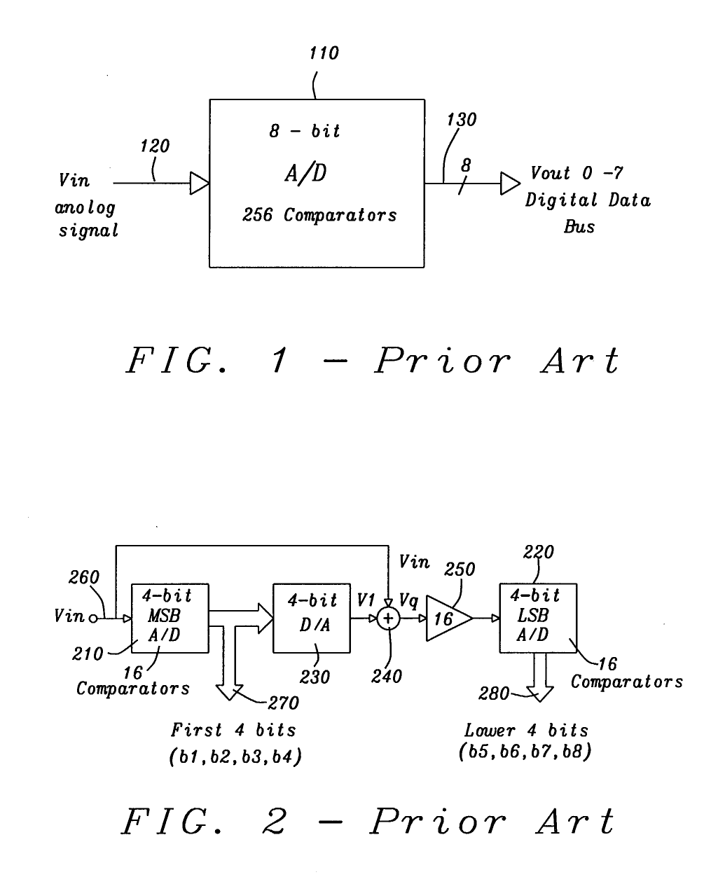

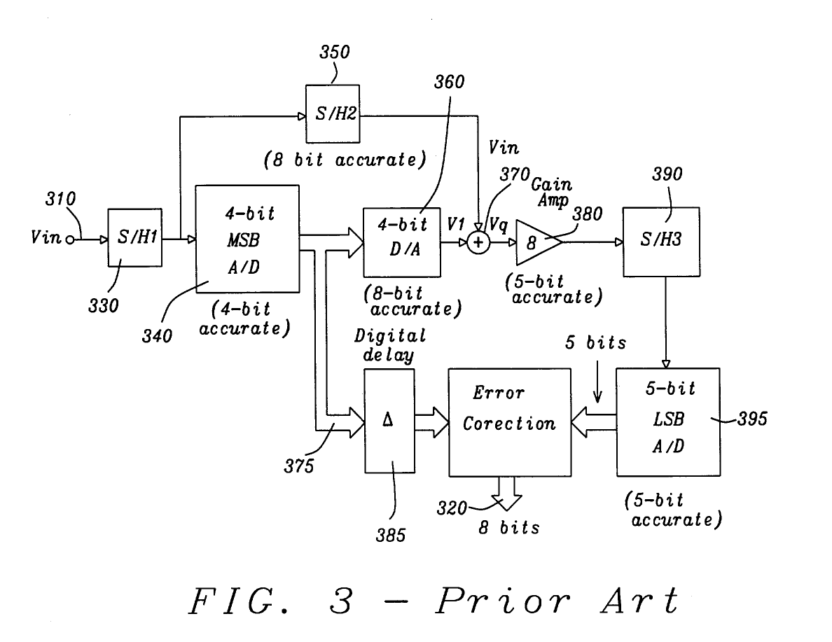

### DESCRIPTION OF THE PREFERRED EMBODIMENT

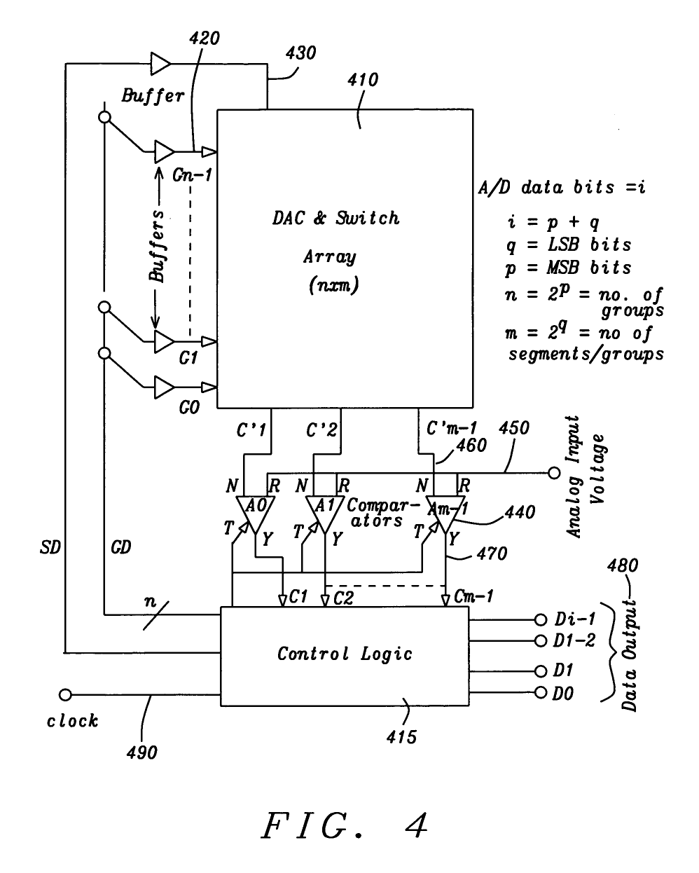

FIG. 4 shows a block diagram of the main embodiment of this invention. There are 4 main sections of this diagram. The digital-to-analog converter DAC and switch array (n×m) 410 is a main component interfacing data buffers 420 and comparators 440.

Secondly, the control logic section 415 provides the primary outputs 480 of this embodiment. Third, the comparators 440 take in the primary input of this embodiment. Last, the data buffer section 420 drives the DAC and switch array 410.

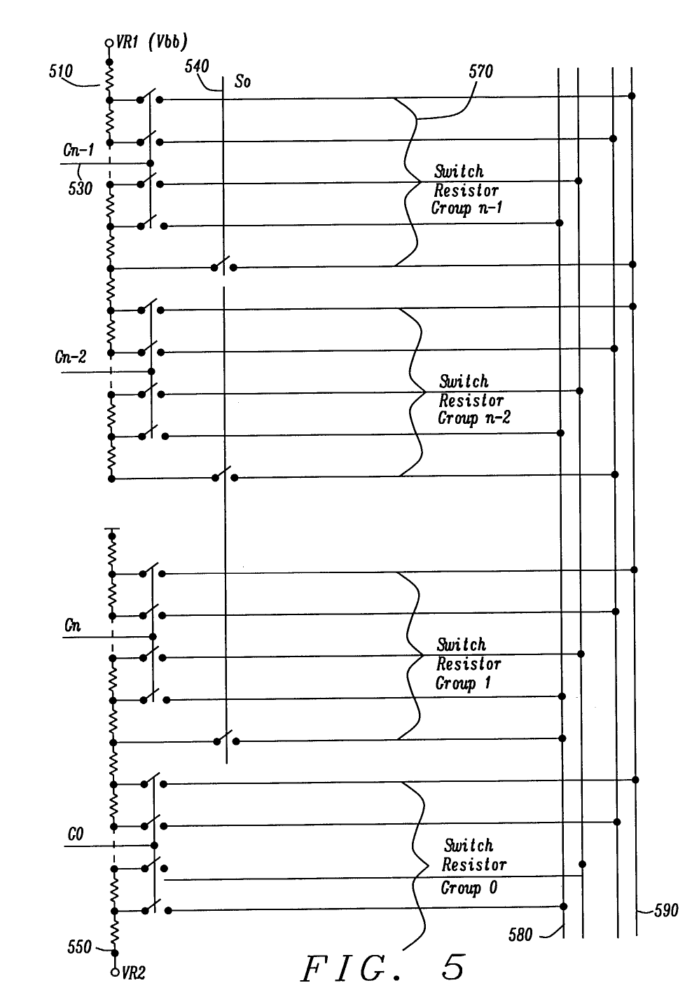

In FIG. 4, the DAC and switch array, which organized n by m elements, provides ‘m’, analog outputs c₁-c₍ₘ₋₁₎ 460. These analog outputs 460 are created from the digital inputs G₀-G₍ₙ₋₁₎. The number, m represents the number of segments per group, in the switch array 410. The number, n represents the number of the groups in the switch array 410. The details of groups and segments will be described more fully below in the description of FIG. 5.

In FIG. 4, the ‘m−1’ comparators 440 are used to compare the ‘m−1’ analog outputs from the DAC/switch array block 410 with the primary input analog signal 450. This single analog input signal feeds all ‘m−1’ comparators. This single analog input signal 450 is the primary analog signal input, which is to be converted to digital bits by the main embodiment of this invention, which is an A/D converter. This analog signal ranges from V_{R1} and V_{R2}. V_{R1} and V_{R2} are the voltages of the two terminals of the reference voltage, V_{REF} for the A/D conversion. Therefore, V_{REF}=V_{R1}−V_{R2}. The ‘m’ outputs 470 of the ‘m’ comparators feed the control logic section 415.

The control logic section 415 is shown in FIG. 4. A key input to the control logic section is the clock 490. The various periods of the clock signal indicate which control operation is to take place. The details of these control tasks will be described below in the description of the timing diagram of FIG. 7. The other inputs to the control logic section include the previously described ‘m−1’ comparator outputs 470. In addition, the control logic section has ‘n’ ‘group driver’ output bus GD, which feed the buffers 420, creating control lines G₀-G₍ₙ₋₁₎ which then feed the DAC and switch array 410. Also, there is a ‘segment driver’ SD line 430 from the control logic 415, which is also buffered to generate So control signal that feeds into the DAC/switch array 410. Finally, there is a sample control output line coming out of the control logic 415. This line drives each of the ‘T’ inputs of the ‘m−1’ comparators 440 shown in FIG. 4. This sample output is active when the comparator's ‘m−1’ outputs will be checked and used by the control logic 415.

In FIG. 4, the buffer circuitry buffers the ‘n’ Group diver lines 420 and the one strobe data line 430 going into the DAC and switch array block. The buffer sizes and design are a function of the size of the ‘n’ by ‘m’ switch array 410.

From FIGS. 4 and 5, the DAC is made of a resistor string of n×m=2^{(p+q)}=2^{I} resistors across V_{R1} and V_{R2} (terminal voltages of the voltage reference V_{REF}). The switches, one connected to the bottom of each resistor (except for R₀₀), are divided into ‘n’ groups of ‘m’ resistors/switches each. For any group, one set of switches is controlled simultaneously by the respective group control line G₀-G₍ₙ₋₁₎. Another group of switches connecting to the bottom resistor (except R₀₀) of each group is simultaneously controlled by the control line SD. All the switches are multiplexed to the inputs of ‘m−1’ comparators. These control lines are obtained by buffering (digital buffer) GD and SD control signals from the digital control logic.

FIG. 5 shows the detailed implementation of the DAC and ‘n’ by ‘m’ switch array. There are primary inputs shown in FIG. 5. They include the ‘n’ group switch drivers 530. If a given group driver signal is High, it closes the ‘m−1’-tap switch, which connects the ‘m−1’ nodes of the resistor divider 510 for each group, to the corresponding ‘m−1’ vertical lines 580, 590. These ‘m−1’ vertical array lines C₁ to C₍ₘ₋₁₎ are the ‘m−1’ analog outputs from the DAC and switch array 460 (in FIG. 4).

The control line, SD 540, which comes from the control logic is used to enable comparison by the ‘m−1’ comparators to determine the most significant bits onto the ‘m−1’ output array lines C₁ to C₍ₘ₋₁₎ (580, 590). The group control lines enable comparison of the least significant bits using the same ‘m−1’ comparators.

In FIG. 5, the various voltage taps are produced by connecting a series of resistors between V_{R1} and V_{R2}. The switches multiplex the resistive taps to the comparator inputs.

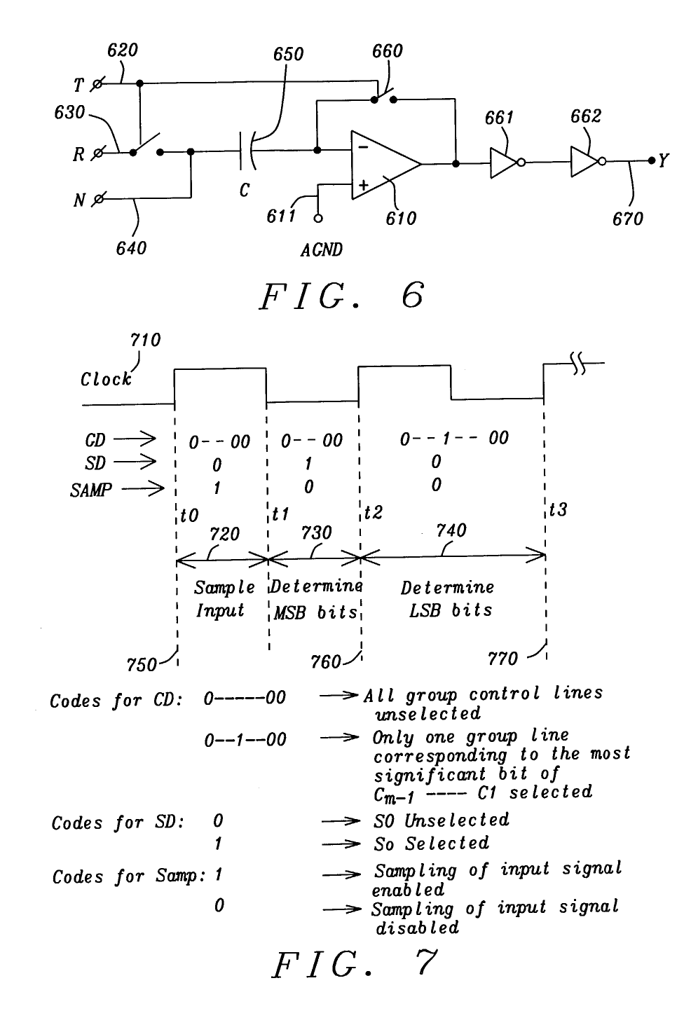

FIG. 6 shows more detail of the comparator schematic. The analog input voltage is sampled on to top plates of the capacitors ‘C’ of the comparators 650 between times To and T1 (FIG. 7) by enabling SAMP signal. The offsets of the comparators are stored on to the bottom plates of ‘C’ 650. During this time all DAC switch control lines are unselected. At time T1, SAMP is disabled, and S0 is selected with G₀-G₍ₙ₋₁₎ unselected, thus applying the DAC input to the comparators. The analog input is thus disabled and each comparator output switches to high or low depending on whether the respective DAC input is higher or lower than the analog input (with the comparator offset being cancelled) and this happens between times T1 and T2. The output pattern of the comparator outputs C₍ₘ₋₁₎-C₁ is a thermometer code. The converter MSB bits, determined by binary coding of this pattern, are latched internally at time T2. At the same time, SO is disabled and only one group control line, the one corresponding to the most significant position of ‘1’s in the above-mentioned thermometer code, is enabled. The MSB thermometer code automatically selects the appropriate group control line for the LSB comparison. The comparators outputs now change to a different thermometer type pattern between times T2 and T3. By binary coding of the new pattern, the LSB bits are determined. At time T3, the LSB and MSB bit data are transferred to the output latch.

The sample signal, T 620 controls when the analog input, R, is sampled and held on capacitor C, 650. The signal N 640 is driven by one of ‘m−1’ analog outputs from the DAC/switch array. In addition, during sample input time, the switch 660 across the output and inverting input of the amplifier 610 helps to store the offset voltage of the amplifier on the bottom plate of the capacitor C. When the sample input 630 is no longer active, the amplifier is ready to do comparison. Also during non-sample time, the capacitor C does not loose any charge, and the analog input voltage is retained across it. This is why the least significant bit, LSB comparison can be done without resampling. The output of the amplifier 610 is buffered via two inverters (661, 662). The comparator output 670 is shown.

FIG. 7 shows the timing diagram of the main embodiment of this invention. The clock 710 shows 2 complete periods. It takes 2 clock periods to describe the full control sequence. The first half of period 1 (720) represents the analog input sample time. The Sample signal SAMP is High and the GD and SD signals are Low. During the second half of period 1 (730), the most significant bits are determined, since the, SD, signal is High and the GD and the Sample signals are Low. During the second period 740, the least significant bits, LSB, are determined. In this case, the SAMP, SD are low, and one of the group control lines determined from the MSB thermometer codes is high.

FIG. 7 shows some edge-triggered events also. Time t₀, 750 is the beginning of the control sequence. Time t₁ ends the sample window and starts the MSB determination period 730. Time t₂, 760 ends the MSB determination time and begins the LSB determination time. Time t₃, 770 marks the end of the LSB determination and triggers the output of ‘I’ data bits from the control logic section.

The advantages of this invention are several. The prior art semi-flash A/D converters use reference subtraction and multiplication, which introduces error and circuit complexity. This invention does not use any subtraction or multiplication operation. This invention utilizes fewer comparators than the prior art semi-flash A/D converters. The prior art designs use 30 comparators for an 8-bit semi-flash A/D converter while this invention uses 15 comparators. Other advantages of this invention are the use of digital control logic and a very simple circuit architecture. In addition, this invention does not require any external Sample and Hold, S/H circuits. Also, this invention uses an offset cancelled comparator design. There is one control line for MSB and n control lines for LSB. Also, thermometer codes of the MSB identifies the right LSB control lines. This invention is a hybrid between flash A/Ds and successive approximation A/D converters.

While the invention has been described in terms of the preferred embodiments, those skilled in the art will recognize that various changes in form and details may be made without departing from the spirit and scope of the invention.

What is claimed is:

1. A semi-flash analog-to-digital, A/D, converter circuit with minimal comparator count comprising:
a digital-to-analog converter, DAC, which communicates to a switch array and with a control logic section, wherein said DAC is comprised of control lines which activate switches which connect groups of resistors including a single control line which activates a last resistor of each of said groups of resistors.
an ‘n’×‘m’ switch array, whose analog outputs connect to comparators to be compared to an analog primary input,
a control logic section which generates signals which control the operation of said DAC and said switch array, which times the operation of said A/D from a time period to subsequent time periods, which controls said comparators, and which latches a primary digital output bus,
a set of comparators, which interface between said DAC and said switch array and between said control logic, and which compare intermediate analog signals from the switch array with said analog primary input, and
a set of buffers, which interface said control logic and said DAC and said switch array.

2. The semi-flash A/D converter circuit of claim 1 further comprising:
a data output bus coming out of said control logic section, and
an analog input line going into one of two inputs of said comparators.

3. The semi-flash A/D converter circuit of claim 1 wherein said DAC, digital-to-analog converter consists of a resistor divider connected between the positive and negative terminals of a voltage reference.

4. The semi-flash A/D converter circuit of claim 1 wherein said DAC has ‘n+1’ digital inputs, which come from n+1 digital outputs from said control logic.

5. The semi-flash A/D converter circuit of claim 1 wherein said DAC has ‘m−1’ analog outputs, which feed one input of said ‘m’ comparators.

6. The semi-flash A/D converter circuit of claim 1 wherein said switch array consists of ‘n’ switch resistor groups each containing ‘m’ switches, which interface different points along said resistor divider and with said ‘m−1’ analog output lines.

7. The semi-flash A/D converter circuit of claim 1 wherein said control logic section consists of a clock input, 8 digital data outputs, ‘m−1’ analog inputs from said comparators, a sampling output, and ‘n’ switch data output digital outputs, which feed into said DAC and said switch array.

8. The semi-flash A/D converter circuit of claim 7 wherein said comparators compare said ‘m−1’ analog outputs from said DAC and said switch array with said single analog primary input signal which is to be converted by said invention to digital signals.

9. The semi-flash A/D converter circuit of claim 7 wherein said comparator uses said sampling output from said control logic to produce ‘m−1’ digital outputs which indicate which of the ‘m−1’ DAC analog outputs equal the voltage level of said primary analog input which comes into said A/D circuit.

10. The semi-flash A/D converter circuit of claim 7 wherein said buffers whose inputs come from ‘n+1’ digital outputs from said control logic, provide adequate drive to control said ‘n+1’ individual switch groups in said DAC and said switch array.

11. The semi-flash A/D converter circuit of claim 7 wherein said clock signal into said control logic defines when to sample input.

12. The semi-flash A/D converter circuit of claim 7 wherein said clock signal into said control logic defines when to determine a plurality of most significant bits.

13. The semi-flash A/D converter circuit of claim 7 wherein said clock signal into said control logic defines when to determine a plurality of least significant bits.

14. The semi-flash A/D converter circuit of claim 7 wherein said clock signal into said control logic defines when to latch said most significant bits.

15. The semi-flash A/D converter circuit of claim 7 wherein said clock signal into said control logic defines when to output a plurality of data bits for previous sample.

16. The semi-flash A/D converter circuit of claim 7 wherein said clock signal into said control logic defines when to output a plurality of data bits for current sample.

17. The semi-flash A/D converter circuit of claim 7 wherein said switch data output from said control logic tells said DAC and said switch array logic when to switch data from ‘n’ resistor group to said ‘m−1’ analog inputs from said DAC and said switch array.

18. The semi-flash AND converter circuit of claim 7 wherein said comparator's digital outputs are coded in a pattern which is a thermometer code, which goes to said control logic where a most significant set of comparator output bits are used to automatically select appropriate group control lines for selecting least significant analog bits in said switch array for comparison with said analog primary input in said comparators.

19. A method of converting an analog signal to a digital signal with a minimal comparator count comprising the steps of:
providing a digital-to-analog converter, DAC, which communicates to a switch array and with a control logic section, wherein said DAC is comprised of control lines which activate switches which connect groups of resistors including a single control line which activates a last resistor of each of said groups of resistors.
providing an ‘n’×‘m’ switch array, whose analog outputs connect to comparators to be compared to an analog primary input,
providing a control logic section which generates signals which control the operation of said DAC and said switch array, which times the operation of said A/D from a time period to subsequent time periods, which controls said comparators, and which latches a primary digital output bus,
providing a set of comparators, which interface between said DAC and said switch array and between said control logic, and which compare intermediate analog signals from the switch array with said analog primary input, and
providing a set of buffers, which interface said control logic and said DAC and said switch array.

20. The method of converting an analog signal to a digital signal of claim 19 further comprising the steps of:
providing a data output bus coming out of said control logic section, and
providing an analog input line going into one of two inputs of said comparators.

21. The method of converting an analog signal to a digital signal of claim 19 wherein said DAC, digital-to-analog converter consists of a resistor divider connected between the positive and negative terminals of a voltage reference.

22. The method of converting an analog signal to a digital signal of claim 19 wherein said DAC has ‘n+1’ digital inputs, which come from n+1 digital outputs from said control logic.

23. The method of converting an analog signal to a digital signal of claim 19 wherein said DAC has ‘m−1’ analog outputs, which feed one input of said ‘m−1’ comparators.

24. The method of converting an analog signal to a digital signal of claim 19 wherein said switch array consists of ‘n’ switch resistor groups each containing ‘m’ switches, which interface different points along said resistor divider and with said ‘m−1’ analog output lines.

25. The method of converting an analog signal to a digital signal of claim 19 wherein said control logic section consists of a clock input, 8 digital data outputs, ‘m−1’ analog inputs from said comparators, a sampling output, and ‘n+1’ switch control digital outputs, which feed into said DAC and said switch array.

26. The method of converting an analog signal to a digital signal of claim 25 wherein said comparators compare said ‘m−1’ analog outputs from said DAC and said switch array with said single analog primary input signal which is to be converted by said invention to digital signals.

27. The method of converting an analog signal to a digital signal of claim 25 wherein said comparator uses said sampling output from said control logic to produce ‘m−1’ digital outputs which indicate which of the ‘m−1’ DAC analog outputs equal the voltage level of said primary analog input which comes into said A/D circuit.

28. The method of converting an analog signal to a digital signal of claim 25 wherein said buffers whose inputs come from ‘n+1’ digital outputs from said control logic, provide adequate device to control said ‘n+1’ individual switch groups in said DAC and said switch array.

29. The method of converting an analog signal to a digital signal of claim 25 wherein said clock signal into said control logic defines when to sample input.

30. The method of converting an analog signal to a digital signal of claim 25 wherein said clock signal into said control logic defines when to determine a plurality of most significant bits.

31. The method of converting an analog signal to a digital signal of claim 25 wherein said clock signal into said control logic defines when to determine a plurality of least significant bits.

32. The method of converting an analog signal to a digital signal of claim 25 wherein said clock signal into said control logic defines when to latch said most significant bits.

33. The method of converting an analog signal to a digital signal of claim 25 wherein said clock signal into said control logic defines when to output a plurality of data bits for previous sample.

34. The method of converting an analog signal to a digital signal of claim 25 wherein said clock signal into said control logic defines when to output a plurality of data bits for current sample.

35. The method of converting an analog signal to a digital signal of claim 19 wherein said switch data output from said control logic tells said DAC and said switch array logic when to switch data from ‘n’ resistor group to said ‘m−1’ analog inputs from said DAC and said switch array.

36. The method of converting an analog signal to a digital signal of claim 25 wherein said comparator's digital outputs are coded in a pattern which is a thermometer code, which goes to said control logic where a most significant set of comparator output bits are used to automatically select appropriate group control lines for selecting least significant analog bits in said switch array for comparison with said analog primary input in said comparators.

37. A comparator circuit which is a key component of a semi-flash analog-to-digital A/D converter comprising:
an amplifier with positive and negative inputs,
an analog input voltage which is a primary input to said semi-flash A/D converter,
a second analog input voltage which comes from an analog output of a digital-to-analog converter and said switch array (DAC and said switch array),
a sampling capacitor, which has a node connected to said negative input of said amplifier and whose other node is connected to either primary analog input voltage or to said analog input from said D/A converter switch array,
an output which connects to a control logic circuit,
a control input, which comes from said control logic circuit and which selectively connects either said primary analog input or said second analog input from said DAC and said switch array to said sampling capacitor and which also selectively connects said amplifier's output to said negative input of said amplifier.

38. The comparator circuit of claim 37 wherein said sampling capacitor is used to cancel the comparator offsets of both said analog primary input and said second analog signals from said DAC and said switch array.

39. The comparator circuit of claim 37 wherein said second analog input represents a set of most significant bits of a desired analog to digital primary outputs during a first time period.

40. The comparator circuit of claim 37 wherein said second analog input represents a set of least significant bits of a desired analog to digital primary outputs during a second time period.

41. The comparator circuit of claim 37 wherein said sampling capacitor retains said analog input voltage after said sampling signal is removed in said first time period allowing comparison of said least significant bits from said DAC and said switch array without performing a second sampling of said analog primary input during said second time period.

42. A digital-to-analog converter and a switch array (DAC and a switch array) sub-circuit which is part of a larger AND converter circuit comprising:
a resistor string of 2^{I} resistors across two reference voltages, where I=the number of digital primary data outputs of said A/D converter circuit, wherein said resistor string of 2^{I} resistors are organized into resistor groups with tap points within said resistor groups,
a series of switches one of which is connected to the bottom nodes of said resistors,
group control lines each of which simultaneously controls a set of said switches,
a second series of switches connected to a bottom or last resistor in said resistors groups, and
a single control line which simultaneously controls said second series of switches connected to said last resistors in said resistor groups.
